(19) United States
(12) Patent Application Publication
(10) Pub. No.: US 2025/0374569 A1
(43) Pub. Date: Dec. 4, 2025

(54) SEMICONDUCTOR DIODE STRUCTURES FOR PRE-PULSE ELIMINATION IN SWITCHING OR PULSING

(71) Applicant: Lawrence Livermore National Security, LLC, Livermore, CA (US)

(72) Inventors: Qinghui Shao, Fremont, CA (US); Caitlin Anne Chapin, Fremont, CA (US); Sara Harrison, Livermore, CA (US); Lars F. Voss, Livermore, CA (US)

(73) Assignee: Lawrence Livermore National Security, LLC, Livermore, CA (US)

(21) Appl. No.: 19/209,588

(22) Filed: May 15, 2025

Related U.S. Application Data
(60) Provisional application No. 63/653,678, filed on May 30, 2024.

(51) Int. Cl. H10D 8/00; H10D 8/01

(52) U.S. Cl. CPC H10D 8/825; H10D 8/045

(57) ABSTRACT

Design and optimization of donor and accepter concentration profiles in a diode structure can be effective at suppressing pre-pulses appearing in high power pulses output by semiconductor opening switches that integrate the diode structure. An example diode structure includes an additional n-type region or layer that is gradually doped. For example, a diode structure includes at least three n-type regions, with the additional n-type region being sandwiched between a n-type region with relatively lower doping and a n-type region with relatively higher doping. The n-type region with relatively higher doping may also feature a doping gradient, and thus, the diode structure can include two n-type regions each having a respective doping gradient. Formation of the additional n-type region with its doping gradient at depth within the diode structure is achievable by gradual introduction of the n-type dopant during crystal growth of the diode structure.

### CROSS-REFERENCE TO RELATED APPLICATIONS

This patent application claims the benefit of priority of U.S. Provisional Patent Application No. 63/653,678, filed on May 30, 2024, the entire contents of which are hereby incorporated by reference.

### FEDERALLY SPONSORED RESEARCH OR DEVELOPMENT

This invention was made with Government support under Contract No. DE-AC52-07NA27344 awarded by the United States Department of Energy. The Government has certain rights in the invention.

### TECHNICAL FIELD

The present disclosure relates to semiconductor structures and doping for improved pulsing and other applications.

### BACKGROUND

Semiconductor opening switches (SOSs) are capable of producing nanosecond high power pulses, and SOSs are widely used as solid-state generators to produce high-power laser, X-ray, and neutron pulses. The pulses produced by SOSs can be characterized by metrics including peak voltage, pulse width, rise time, and repetition rate. Optimization of the pulses produced by SOSs can improve the usage, applicability, and performance of SOSs in various settings.

### SUMMARY

The present disclosure generally relates to improving the performance of a SOS's output pulse through minimizing or eliminating pre-pulses, which extend pulse rise times and pulse durations. According to the disclosed embodiments, pre-pulses can be mitigated through particular donor and acceptor concentration profiles in the semiconductor diode structures making up a SOS. Using semiconductor crystal growth techniques, the particular donor and acceptor concentration profiles, or doping profiles, that mitigate pre-pulses can be achieved. In particular, certain technical solutions disclosed herein involve a gradually doped n-type region between a base n-type region and a highly doped n-type region.

In one example aspect of the disclosed technology, a semiconductor diode structure includes one or more p-type regions positioned contiguously in the semiconductor diode structure to a first depth within the semiconductor diode structure. The semiconductor diode structure further includes at least three n-type regions positioned contiguously starting from the first depth of the semiconductor diode structure. Two of the n-type regions are defined past a second depth within the semiconductor diode structure (down to an end of the semiconductor diode structure). These two regions below the second depth include a first n-type region having a first doping gradient and a second n-type region having a second doping gradient. The second doping gradient is defined by a greater change in dopant concentration per unit of depth compared to the first doping gradient.

In another example aspect, a SOS for producing a high power pulse includes a plurality of semiconductor diode structures chained in series. Each semiconductor diode structure includes one or more p-type regions positioned contiguously to a first depth within the semiconductor diode structure. The semiconductor diode structure further includes two n-type regions having different doping gradients. The two n-type regions are positioned past a second depth within the semiconductor diode structure.

In yet another example aspect, a method for manufacturing a SOS for pulse generation is provided. The SOS includes a series of semiconductor diode structures. The method includes growing at least a portion of a semiconductor diode structure from a crystal substrate. The portion of the semiconductor diode structure includes a first n-type region located at an end of the semiconductor diode structure (i.e., an end adjacent to the crystal substrate, an end from which the semiconductor diode structure is grown). This first n-type region has a first doping gradient. The portion of the semiconductor diode structure further includes a second n-type region positioned immediately deeper/internal to the first n-type region and having a second doping gradient.

In yet another example aspect, a method is disclosed. The method includes selecting a first depth for a p-type portion of a semiconductor diode structure based on a range of desired peak voltages for an output pulse to be produced by a switch device including a plurality of the semiconductor diode structures. The method further includes selecting a second depth for a n-type portion of the semiconductor diode structure. The second depth is selected to optimize at least a rise time of the output pulse given the first depth for the p-type portion. The method further includes manufacturing the semiconductor diode structure according to the first depth and the second depth. Manufacturing the semiconductor diode structure includes growing the n-type portion, from an end of the semiconductor diode structure to the second depth, to two different doping gradients.

The above and other aspects and their implementations are described in greater detail in the drawings, the descriptions, and the claims.

### BRIEF DESCRIPTION OF THE DRAWINGS

FIG. 1A illustrates a schematic of an example semiconductor opening switch (SOS) switching/pumping circuit for pulsing a load.

FIG. 1B illustrates an example doping profile through a depth of a semiconductor diode structure.

FIG. 1C illustrates an example of multiple pulses output by a SOS.

FIG. 2A illustrates doped regions of an example semiconductor diode structure for a SOS.

FIG. 2B illustrates example doping profiles through a depth of a semiconductor diode structure.

FIG. 2C illustrates example voltage pulses output for various doping profiles for a semiconductor diode structure.

FIGS. 2D-2I illustrate example simulation results of SOS characteristics over time.

FIG. 3A illustrates doped regions of an example semiconductor diode structure for a SOS.

FIG. 3B illustrates example doping profiles through a depth of a semiconductor diode structure.

FIG. 3C illustrates example voltage pulses that are output for various doping profiles for a semiconductor diode structure.

FIG. 4 shows an example process for manufacturing switching/pulsing devices with semiconductor diode structures, according to embodiments of the disclosed technology.

### DETAILED DESCRIPTION

Disclosed embodiments include devices, systems, and methods related to mitigating pre-pulses in high power pulses (i.e., reducing rise time and duration) that are output by semiconductor opening switches or semiconductor-based switching/pulsing systems. Certain doping profiles or doped region/layer configurations of semiconductor diode structures can cause the pre-pulses to be suppressed. These profiles or configurations include an additional n-type region that is gradually doped with respect to a depth therethrough. The doping gradient for this additional n-type region effectively transitions or buffers between a high doping concentration in a highly doped n-type region and a lower doping concentration in a base n-type region. In some embodiments, the highly doped n-type region may also feature a doping gradient, although steeper than the doping gradient of the additional n-type region, and thus, the semiconductor diode structure may include at least two n-type regions that are each gradually doped with respective gradients. Inclusion of the additional n-type region with a gradual doping avoids or minimizes the formation of high field regions (HFR) within the diode structure that contribute to the appearance of pre-pulses.

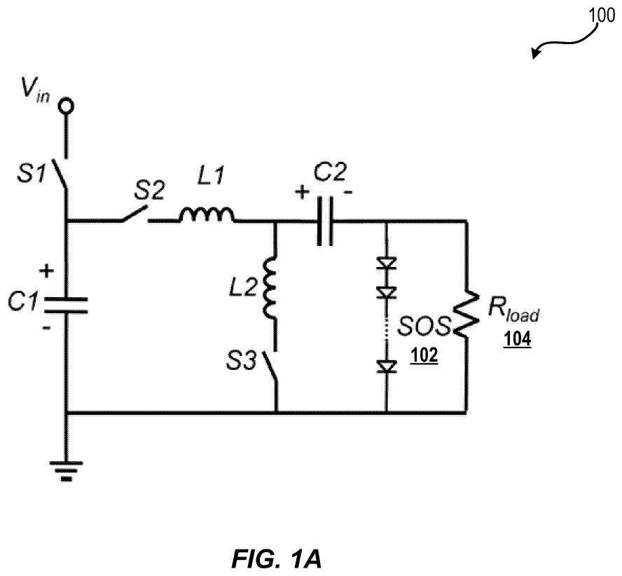

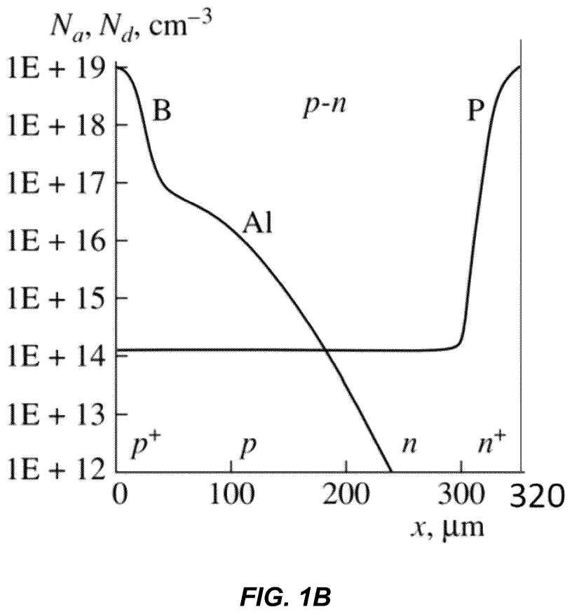

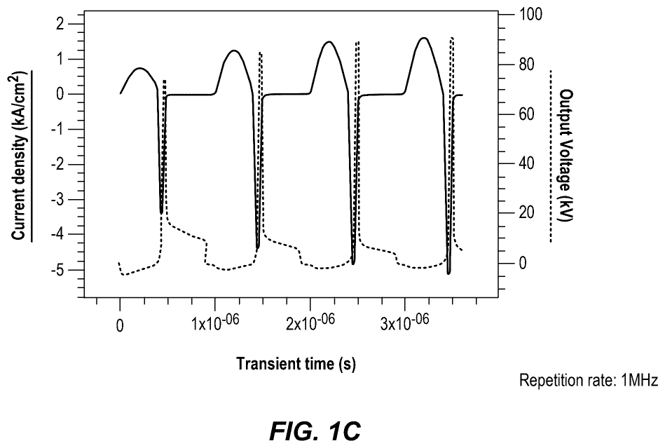

FIG. 1A illustrates a schematic of an example of a circuit 100 that is configured for pumping a semiconductor opening switch, SOS 102, to pulse a load 104. The SOS 102 is composed of multiple semiconductor diode structures that are stacked or connected in series, which increases the output voltage of the SOS 102. These diode structures making up the SOS 102 are connected end-to-end, for example, such that a n-type end of one diode structure is adjacent or coupled to the p-type end of another diode structure. The SOS 102 may include conductive epoxy between individual diode structures.

In order to pump the SOS 102, switches S2 and S3 are open at time t=0, while switch S1 is closed to charge capacitor C1. At the beginning of direct pumping, switch S1 is open, and switch S2 is closed to charge capacitor C2 through the inductor L1 and SOS 102. The excess electrons and holes are stored in the SOS 102. At the time at which current in the loop reaches zero, the energy stored in capacitor C2 is maximized. Switch S2 is then opened to terminate the direct pumping process. Switches S1 and S3 are then closed to start the reverse pumping process. The excess carriers are extracted from the SOS 102 by reverse current flowing in the loop of capacitor C2, inductor L2, and the SOS 102. A space-charge region begins to build in the diode structures in the SOS 102. The propagation speed of space-charge region is proportional to the reverse pumping current. Once the internal resistance of the SOS 102 is much higher than the resistance of the load 104, the current through the SOS 102 is cut off, and a large current is forced to flow through the load 104, producing a high voltage pulse. The process is very quick and typically in the range of nanoseconds. Table 1 below includes example circuit parameters for pumping the SOS 102 and pulsing the load 104. The parameter n_{diode} refers to the number of diode structures that are stacked to form the SOS, and the parameter A refers to a cross-sectional area of the diode structures.

TABLE 1

| C₁ (nF) | C₂ (nF) | L₁ (μH) | L₂ (μH) | R_{load} (Ω) | n_{diode} | A (cm²) | Vᵢₙ (kV) |
|---|---|---|---|---|---|---|---|
| 3.8 | 3.8 | 8.53 | 1.07 | 200 | 160 | 0.24 | 32 |

The following example results summarize the simulated performance, with the circuit parameters of Table 1, of a SOS featuring diode structure doping according to the example illustrated in FIG. 1B.
Size: 0.24 cm²
Number of structures: 160
Input voltage: 32 kV
Direct pumping time: 400 ns
Reverse pumping time: ˜52 ns [100 ns w/short circuit]
Max output voltage: 91 kV
FWHM of output voltage: 13 ns
BV static and dynamic: >568 V/structure (dynamic) (should be much higher)
Peak operating current: 5.1 kA/cm2, 1.2 kA (reverse), 1.6 kA/cm2, 384 A (direct)
Pulse frequency: >1 MHz
Switching time 1:19 ns, 90%-10% of max reverse current [400 ns direct pumping time] (pre-pulse included).
Switching time 2:3.1 ns, 40%-90% of max output voltage (pre-pulse excluded)
dV/dt: 14.7 kV/ns [40%-90% of max output voltage]
dI/dt: 0.17 kA/ns [10%-80% of max reverse current]

Pre-pulses in the pulse produced for the load 104 appear when the SOS 102 is composed of diode structures being doped as indicated in FIG. 1B. As a result, such SOS devices fall short of various performance requirements in some applications. Example performance requirements or ideal performance characteristics are listed below.
BV: >800V (with FWHM<1 ns); or >600V (with FWHM<5 ns).
Peak repetitive operating current: 25 A/mm³.
Pulse repetition freq.: 100 kHz (static) to 1 MHz (dynamic) (FIG. 1C illustrates an example of multiple pulses output by the SOS at a rate of 1 MHz).
Switching time: <1 ns for 80 ns or <3.5 ns for 200 ns of pumping time.
Differential voltage (−dV/dt): 2 kV/ns.
Stackable design with low resistance loss.
Form factor: circular with a diameter of 0.25″-0.8″.

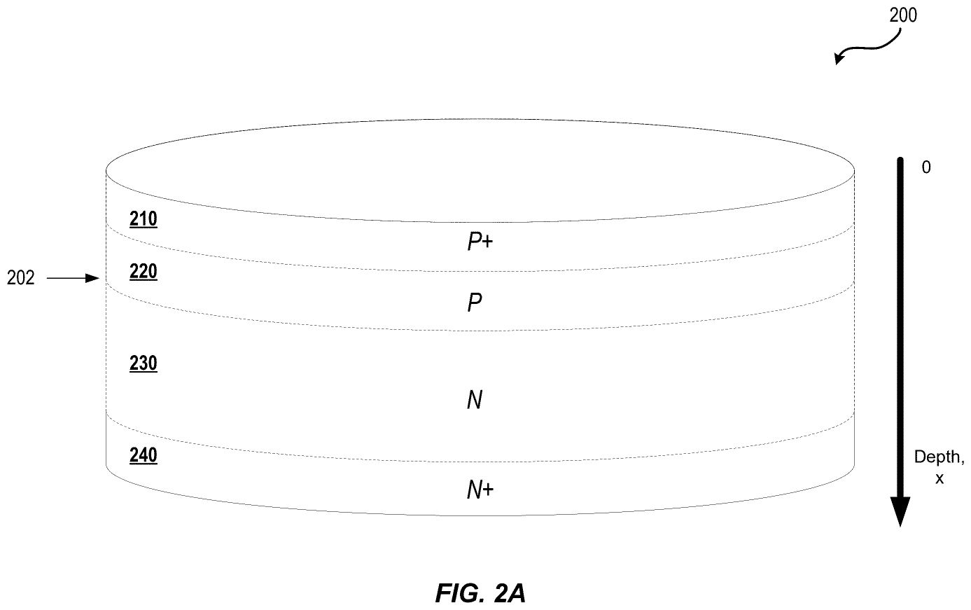

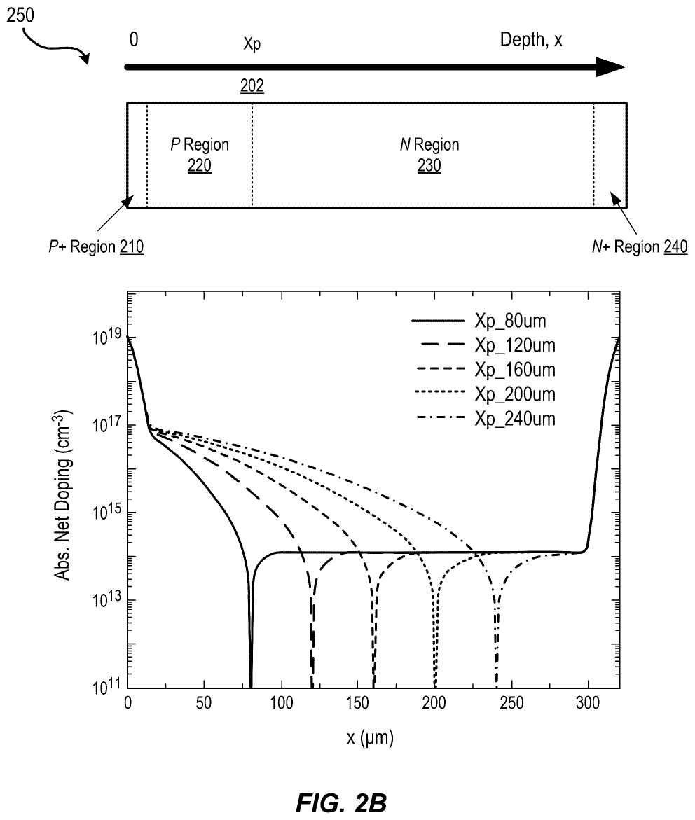

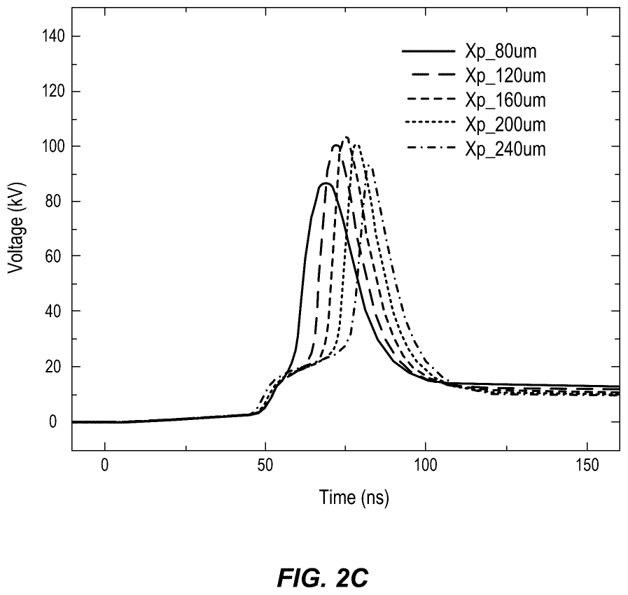

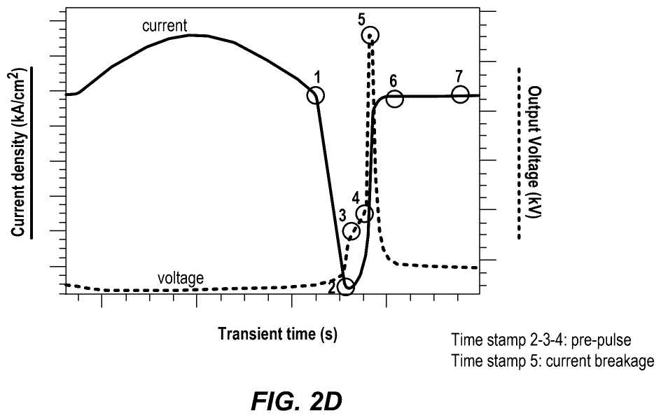

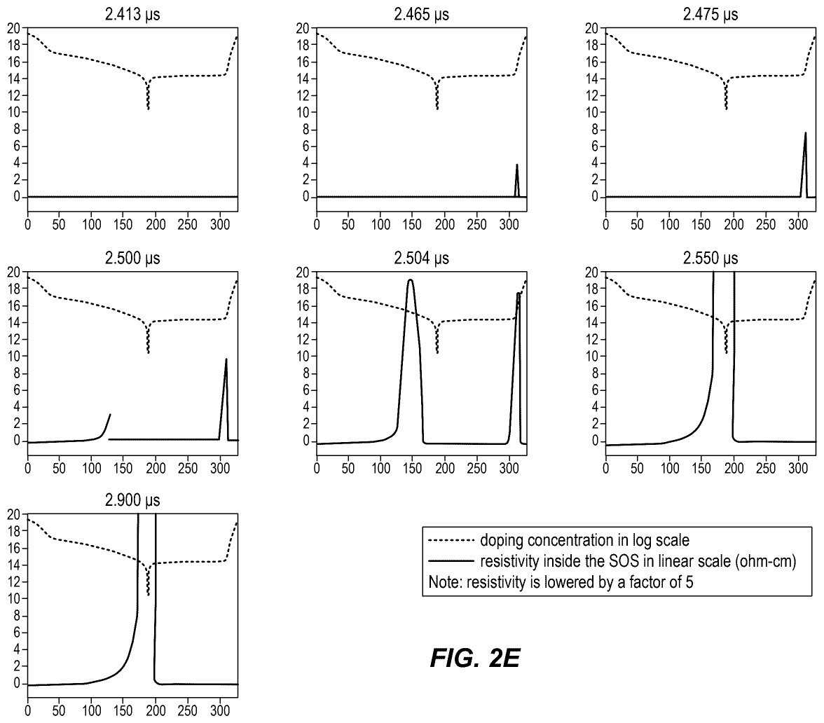

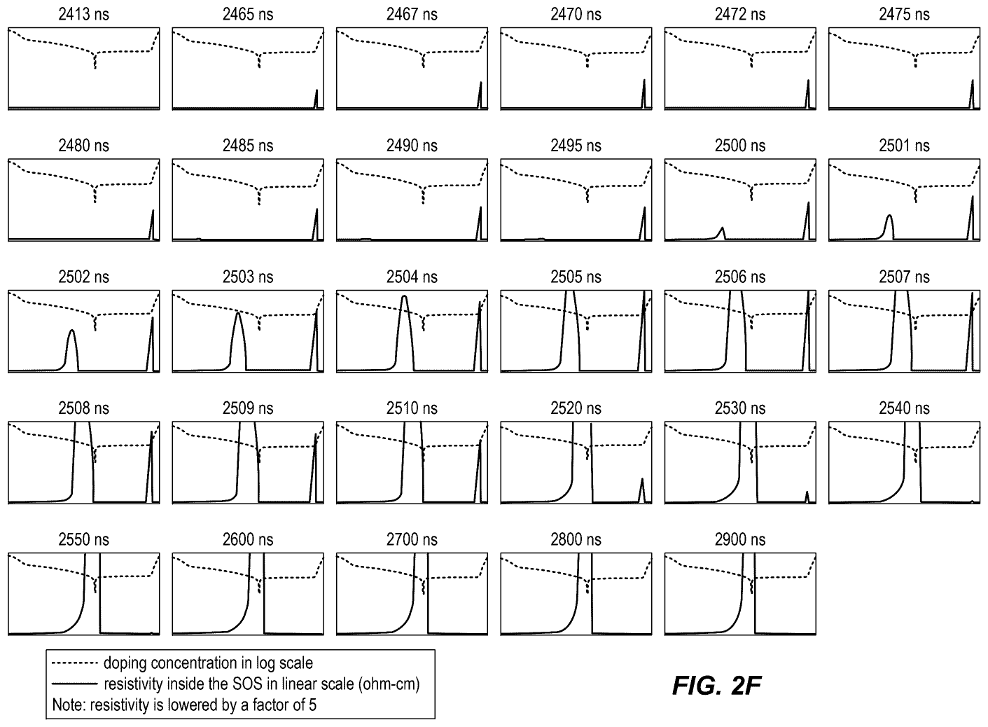

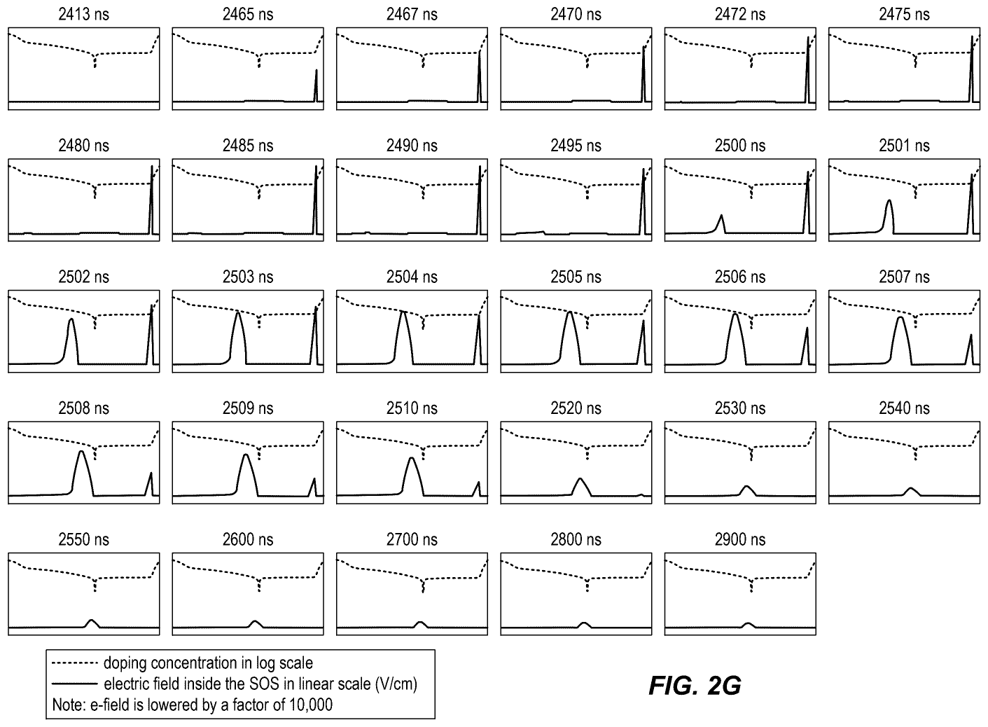

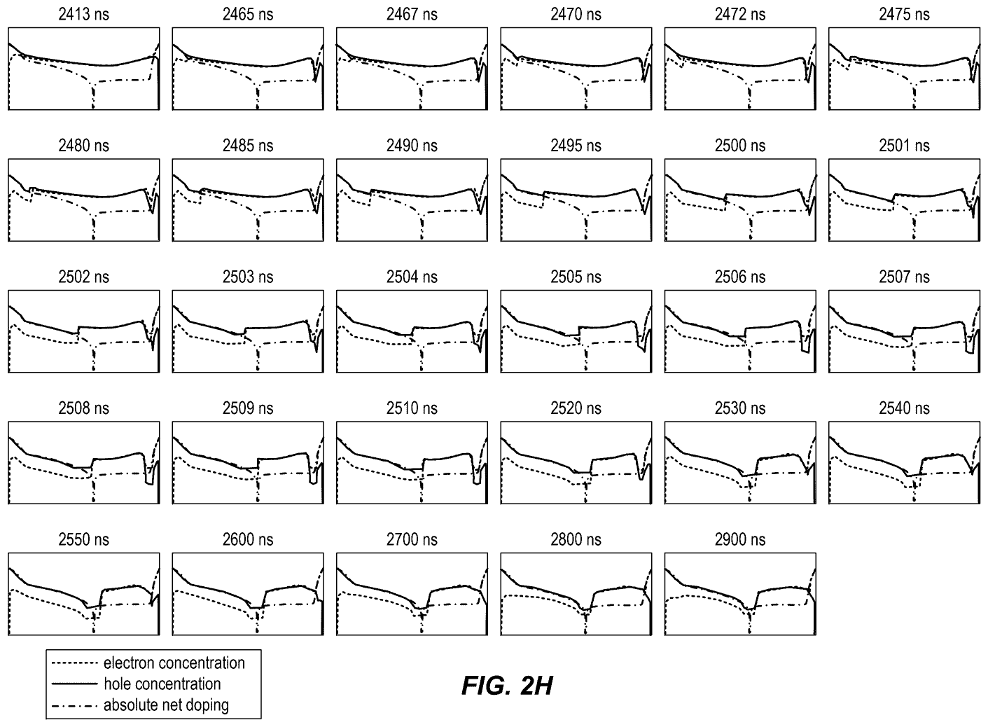

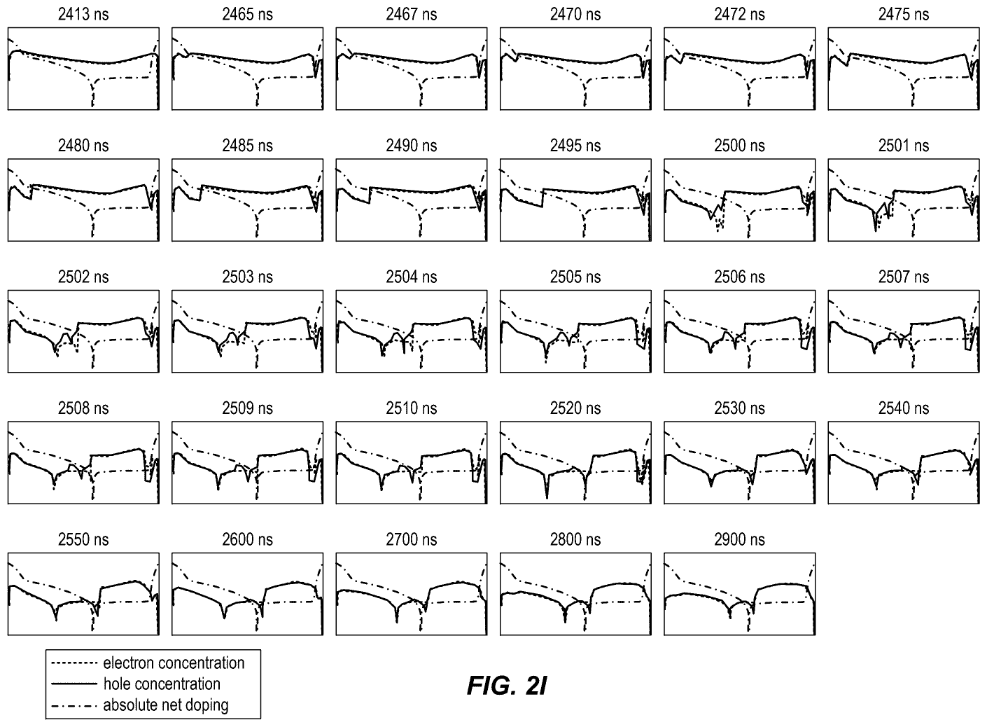

FIG. 2A illustrates a diode structure 200 consistent with the doping profile indicated in FIG. 1B. Si-based SOS diodes such as the diode structure 200 are typically formed by donor and acceptor diffusion from both sides into a highly resistive wafer. In some examples, the diode structure 200 is manufactured starting with a n-type Si wafer, diffusing a first p-type dopant (e.g., boron) to form a P+ region 210 (i.e., a first p-type region), diffusing a second p-type dopant (e.g., aluminum) to form a P region 220 (i.e., a second p-type region), and diffusing a n-type dopant (e.g., phosphorus, arsenic, antimony) from the wafer backside to form the N+ region 240. The n-type dopant diffusion from the backside only reaches a limited depth of the wafer, and the remaining space between the N+ region 240 and the P region 220 constitutes a N region 230 (also referred to as a N-base region) based on the n-type doping of the original Si wafer.

The junction depth 202 (also referred to as Xₚ) between the P region 220 and the N-base region, or generally between the p-type portion and the n-type portion of the diode structure 200, is controlled by diffusion temperature and time. The junction depth 202 has effects on at least the current cutoff in the SOS 102, which are demonstrated in FIGS. 2B and 2C. Generally, in some examples, an increase of Xₚ from 80 μm to 200 μm (for a 320 μm deep structure) can increase the overvoltage coefficient from one to six.

FIGS. 2B and 2C in particular show example plots illustrating that the junction depth 202 can affect a peak voltage of the pulse output by a SOS. The example results shown in FIGS. 2B and 2C are produced by mixed-mode technology computer aided design (TCAD) simulations. In the simulations, the diode structure is built from a 320 μm thick Si wafer with a n-type background doping of 1.25×10¹⁴ cm⁻³ and a high resistivity of 50 Ω-cm. The acceptor doping profiles are expressed by two complementary error functions, one with peak concentration of 1×10¹⁹ cm⁻³ and junction depth of 20 μm, and the other with peak concentration of 1×10¹⁷ cm⁻³ and a junction depth that is variable in the simulation (Xₚ). The donor profile is expressed as a complementary error function with peak concentration of 1×10¹⁹ cm⁻³ with a high-low junction depth of 20 μm. 160 of such structures with an effective area of 0.24 cm² are stacked together. The concentration and field dependent mobility, Shockley-Read-Hall recombination, Auger recombination, and Selberherr impact ionization models are enabled in the mixed-mode simulations. The input voltage is set to 32 kV. The operating repetition rate is set to 1 MHz, and the direct pumping time is set to 400 ns. Additional details of device structure and circuit element parameters are listed in Table 1.

FIG. 2B depicts different doping profiles for the variable Xₚ junction depth. The upper portion of FIG. 2B illustrates a doping profile 250 that approximately corresponds to a junction depth 202 set at 80 μm for a 320 μm structure, as plotted in the graph in the lower portion of FIG. 2B (“Xp_80 um”). The graph in FIG. 2B illustrates net doping concentrations for different junction depths, including 80 μm, 120 μm, 160 μm, 200 μm, and 240 μm. Varied junction depths affect the sizes of the P region 220 and the N region 230.

From the example results in FIG. 2C that correspond to the various doping profiles in FIG. 2B, it can be seen peak voltage increases first from 86.8 kV to 103 kV as Xₚ increases from 80 μm to 160 μm, then drops with Xₚ above 160 μm. Pre-pulses are observed for the entire Xₚ range simulated, which seriously degrade at least the voltage pulse rise time and peak voltage. They originate from a high field region (HFR) formed at N/N+ regions (e.g., in the N+ region near the N-N+ junction) during the reverse pumping process, which is suggested by the same onset time featured across the different structures. When the HFR's resistance is comparable to the load resistance, some amount of current is forced to flow through the load, and a slowly increasing voltage pulse is generated. Meanwhile, another HFR is formed in the P region (e.g., the P-N-base junction). As this HFR propagates towards the junction between the P region and the N-base region (i.e., at the junction depth 202), a very high resistive region is quickly formed, therefore the conducting current is intercepted, and high voltage pulse is produced. FIG. 2D illustrates a plot that demonstrates the current breakage that leads to the pre-pulse.

FIGS. 2E-2I illustrate example time evolution results measuring SOS performance that demonstrate the appearance of pre-pulses and the causes thereof. In particular, FIGS. 2E-2F show resistivity within the SOS over time, FIG. 2G shows the electric field inside the SOS over time (the total area below the e-field curve is the total voltage drop across the SOS(R_load)), FIG. 2H shows the carrier concentration within the SOS over time, and FIG. 2I shows the plasma concentration within the SOS over time.

One approach to suppressing the pre-pulses is to reduce Xₚ, or the junction depth 202. A shorter Xₚ gives a relative longer base, and a lower average plasma (i.e., excess electrons and holes) concentration. As a result, the interception process at the p-n junction takes place earlier, and the main voltage pulse is pushed and merged into the pre-pulse. However, this approach reduces the output peak voltage by 16%. Increasing Xₚ beyond 160 μm, the pre-pulses become more evident. These example results of peak voltages and rise time are summarized in Table 2. The results suggest that pre-pulses cannot be eliminated without degrading the peak voltage. Thus, it is demonstrated here that the pre-pulses cannot be eliminated by simply changing Xₚ through the frontside p-type dopant (e.g., aluminum) diffusion.

TABLE 2

| Xₚ (μm) | 80 | 120 | 140 | 160 | 180 | 200 | 240 |
|---|---|---|---|---|---|---|---|
| Peak voltage (kV) | 86.8 | 99.8 | 102.2 | 103.3 | 102.6 | 101.1 | 93.5 |
| Rise time (ns) | 13.7 | 17.2 | 18.6 | 20.4 | 22.6 | 25.3 | 30.8 |

According to aspects of the present disclosure, an optimized diode structure that includes an additional n-type region that is gradually doped, or features a doping gradient, is effective at suppressing the pre-pulses induced by the diode structures discussed above. The disclosed technical solutions avoid compromising the peak voltage while still being effective at suppressing pre-pulses. To achieve these dopant concentration profiles that include the additional n-type region, conventional diffusion processes requires extensive time and high temperature (e.g., tens of days at 1100 degrees C.) to be able to diffuse phosphorus or similar n-type dopants deep into the wafer. But Si chemical vapor deposition (CVD) epitaxial techniques with in situ doping enable the ability to achieve nominally arbitrary n-type or p-type doping profiles, for example, in 300-400 μm thick wafer with a low background doping (˜1×10¹⁴ cm⁻³).

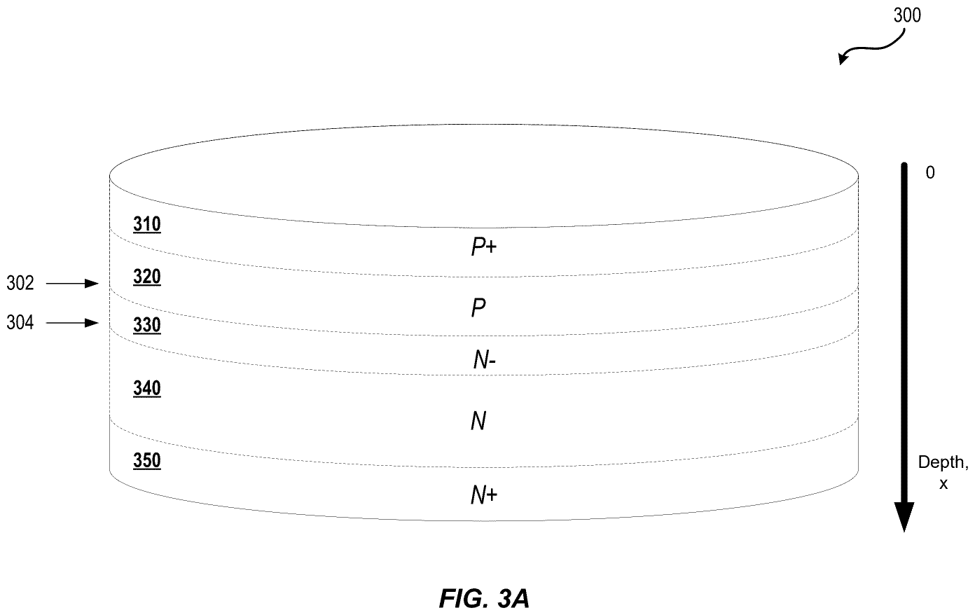

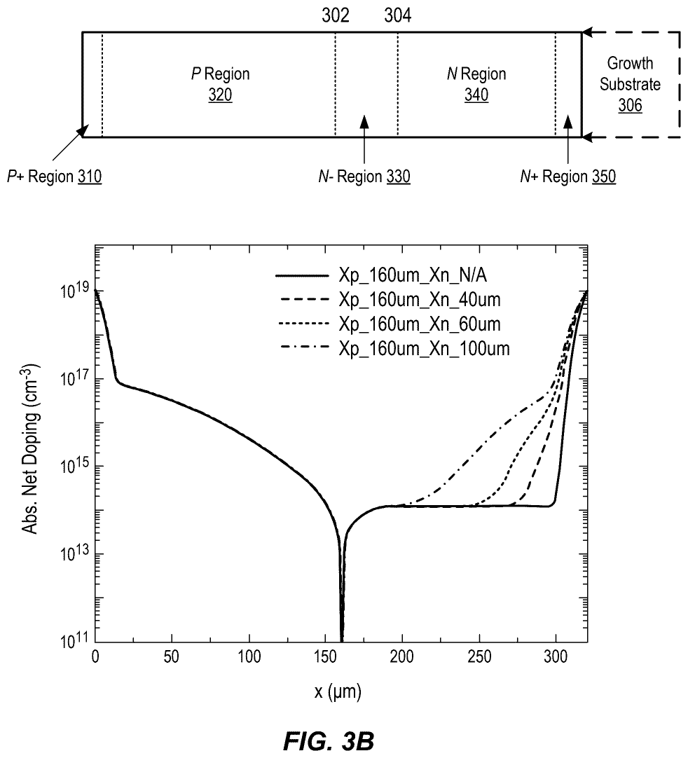

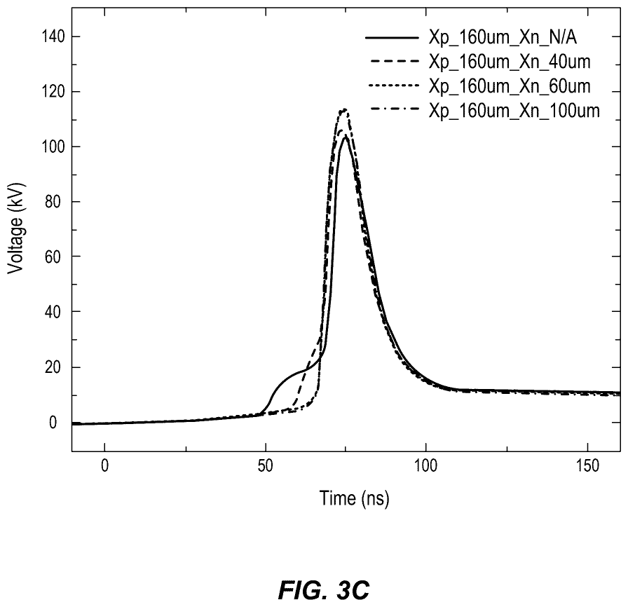

FIG. 3A illustrates a diode structure 300 for suppressing or mitigating pre-pulses, by including the additional n-type region with a doping gradient. In FIG. 3A, the diode structure 300 includes p-type regions layered from its top end or face (i.e., depth x=0) to a p-n junction depth 302 (i.e., Xp). These include the P+ region 310 and the P region 320. The rest of the diode structure 300, from the p-n junction depth 302 down to the bottom end, includes at least three n-type regions that are layered on one another. The at least three n-type regions include the additional gradually-doped n-type region, or N region 340, sandwiched between two other n-type regions, the N− region 330 and the N+ region 350. The N region 340 featuring the gradual doping begins at a gradient depth 304 and continues down until the N+ region 350. The gradual doping or doping gradient may be defined by a change in dopant concentration over a change in depth. Accordingly, the dopant concentration changes across depths within the N region 340 according to a function, such as an error function, a parabolic function, a logarithmic function, an exponential function, and/or the like.

In some embodiments, the N+ region 350 is also gradually doped, while the N− region 330 is uniformly doped (e.g., according to the background doping of the wafer). It should be understood that the labeling of + or − only refers to the relative amount or concentration of dopant and does not suggest electrical charges of dopants in those regions. Thus, the gradient depth 304 defines where gradual n-type doping can be found, and the diode structure 300 can feature at least two different n-type doping gradients below the gradient depth 304.

At least the N region 340 and the N+ region 350 may be introduced from the backside of the wafer during crystal growth. In some embodiments, the N region is formed by donor diffusion or in situ doping during the crystal growth. For example, the upper portion of FIG. 3B illustrates a growth substrate 306 from which the diode structure 300 is grown from its backside. Starting from the growth substrate 306, the N+ region 350 is formed first (e.g., via diffusion or in situ doping during the crystal growth), followed by the N region 340 (e.g., via diffusion or in situ doping during the crystal growth). In some embodiments, the remaining regions may also be formed during growth, with p-type dopants being diffused or in situ doped during crystal growth to form the P+ region 310 and the P region 320. Alternatively, the remaining regions may be formed after growth; for example, the P+ region 310 and the P region 320 are formed through the conventional diffusion techniques after the diode structure 300 is grown. In some embodiments, the n-type dopant used at least for the N region 340 may be a dopant with higher diffusivity, such as phosphorus (rather than arsenic, for example), so as to reach the depth selected for the N region 340. That is, the n-type dopant for the diode structure may be selected based on a depth of the N region 340 or generally the region configuration.

FIGS. 3B and 3C illustrate example results that demonstrate the effectiveness of the diode structure 300 at mitigating pre-pulses. In these results, the gradient depth 304 (Xₙ) is varied after fixing the p-n junction depth 302 (Xₚ). In practice, this approach of first fixing or selecting the p-n junction depth 302 avoids degrading peak voltage for the sake of pre-pulse mitigation. In the illustrated embodiments, the p-n junction depth 302 (Xₚ) is fixed at 160 μm, which had resulted in the maximum peak voltage (see Table 2). In FIG. 3B, the graph shows dopant concentration profiles for Xₙ values of 0 μm, 40 μm, 60 μm, and 100 μm. Here, the values for Xₙ specifically refer to the size of the N region 340, or the range of depths spanned by the N region 340 starting from the N+ region 350. Thus, an Xₙ value of 0 μm refers to a lack of a N region 340. But for example, the upper portion of FIG. 3B shows a doping profile that approximately corresponds to an Xₙ value of 100 μm.

The example pulse results of FIG. 3C are produced by simulating the formation of the N region 340 with a peak concentration of 1×10¹⁷ cm⁻³ at the structure backside. As shown, the onset time of pre-pulses is delayed with increased Xₙ because the donor concentration gradient in N region is reduced compared to N+ region where the plasma front resides. The pre-pulse is totally merged to the main pulse when Xₙ is greater than 60 μm. As a result, the peak voltage is further increased by 10%, and the rise time is reduced from 20.4 ns to 5.5 ns. Further increasing Xₙ up to 140 μm did not change the waveform shape or rise time, but slightly dropped the peak voltage. The example results of peak voltages and rise time are summarized in Table 3 below.

TABLE 3

| Xₙ (μm) | N/A | 40 | 60 | 80 | 100 | 120 | 140 |
|---|---|---|---|---|---|---|---|
| Peak voltage (kV) | 103.3 | 105.6 | 113.9 | 115.2 | 115.5 | 114.7 | 113.1 |
| Rise time (ns) | 20.4 | 10.7 | 5.5 | 5.5 | 5.5 | 5.5 | 5.5 |

In summary, an optimized diode structure for an SOS includes a layer of gradually changed n-type doping. While conventional techniques of backside diffusion are prohibitive in forming this additional n-type layer, the layer can be formed by diffusion or in situ doping during the crystal growth. The incorporation of this additional n-type layer effectively eliminates the pre-pulse, increases the peak voltage, and reduces the pulse rise time.

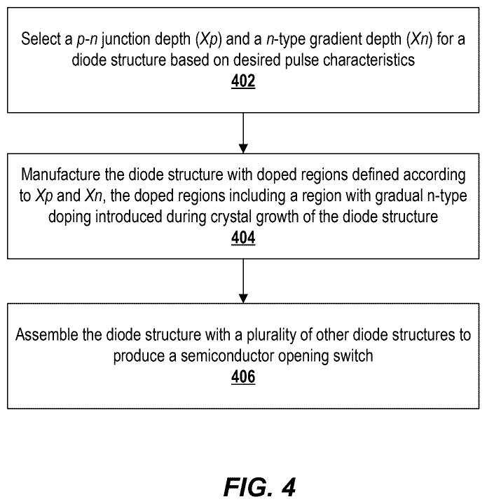

FIG. 4 shows an example method for optimizing and manufacturing semiconductor-based switching/pulsing devices with suppressed pre-pulse behavior. At 402, the method includes selecting a p-n junction depth (Xₚ) and a n-type gradient depth (Xₙ) for a diode structure based on desired pulse characteristics. In some embodiments, the p-n junction depth is selected first from a plurality of candidate p-n junction depths. Each of the candidate p-n junction depths are simulated to determine a corresponding output pulse peak voltage, and a particular p-n junction depth is selected according its corresponding output pulse peak voltage (e.g., a maximum peak voltage, a second maximum peak voltage, a desired peak voltage).

After selecting the p-n junction depth, a n-type gradient depth is selected to optimize pre-pulse suppression, or to minimize rise time of the output pulse. For example, multiple candidate n-type gradient depths can be simulated to determine corresponding rise times, and a particular n-type gradient depth is selected according to its corresponding rise time (e.g., a minimum rise time, a second minimum rise time, a desired rise time).

In some embodiments, pre-pulse suppression may be prioritized over peak voltage. Accordingly, the n-type gradient depth may be selected before selecting the p-n junction depth, in some examples. In other examples, a two-dimensional optimization may be performed to select a pairing of a p-n junction depth and a n-type gradient depth that minimizes rise time (with less consideration or weight given to the maximization of peak voltage).

At 404, the method includes manufacturing the diode structure with doped regions according to the p-n junction depth and the n-type gradient depth. At least one of the doped regions is a region with a (depth-wise) gradual n-type doping that is introduced during crystal growth of the diode structure. The diode structure, or at least a portion thereof, may be grown from a crystal substrate. Growth of the diode structure begins from its backside, so that the n-type portion of the diode structure is grown first, followed by the p-type portion. In some embodiments, the doped regions are introduced or formed during or concurrent with the crystal growth of the diode structure. To do so, n-type dopants and p-type dopants may be introduced into the semiconductor epitaxial layers via in situ doping or diffusion.

In order to assure dopant introduction at depth (e.g., to the n-type gradient depth), at least the n-type regions of the diode structure are formed concurrent with crystal growth. In some embodiments, the p-type regions are also formed concurrent with crystal growth. Alternatively, the p-type regions are formed subsequent to crystal growth via conventional diffusion techniques. Whether formation of p-type regions occurs during or subsequent to crystal growth may be based on the selected p-n junction depth. For example, if the selected p-n junction depth is relatively deep so as to induce long diffusion times or resource consumption, then the p-type regions may be formed during crystal growth.

As discussed, the n-type regions of the diode structures include doping gradients. The doping gradients may be introduced during crystal growth by varying the rate of dopant introduction as the diode structure is grown upwards (e.g., by controlling the mass flow of doping precursors with a mass flow controller). Alternative to a doping gradient that is described by an error function, a gradient that is parabolic, exponential, logarithmic, or another geometry may be introduced in the n-type region(s) of the diode structure, again through controlling the rate of dopant introduction.

At 406, the method includes assembling the diode structure with a plurality of other diode structures to produce a semiconductor opening switch. In some embodiments, the diode structure is grown with the plurality of other diode structures in a common panel, wafer, substrate, and/or the like. In doing so, the diode structure and the plurality of other diode structures may be identically configured with respect to their doping profiles; that is, Xₚ and Xₙ is consistent across all of the diode structures in the common wafer. Accordingly, the diode structure and the plurality of other diode structures may be cut or singulated from the common wafer. When assembling the diode structures together, conductive epoxy may be inserted between each pair of diode structures to secure the diode structures together. Terminals may be formed at each end of the series of diode structures, so that the semiconductor opening switch can be integrated into a circuit for pulsing a load.

Some example technical solutions implemented by example embodiments are listed below.

1. A semiconductor diode structure comprising: one or more p-type regions positioned contiguously in the semiconductor diode structure to a first depth (e.g., Xₚ) within the semiconductor diode structure; and at least three n-type regions positioned contiguously starting from the first depth of the semiconductor diode structure, the at least three n-type regions comprising: a first n-type region (e.g., an N region) followed by a second n-type region (e.g., an N+ region) positioned past a second depth (e.g., Xₙ) within the semiconductor diode structure, wherein the first n-type region has a first doping gradient and the second n-type region has a second doping gradient that is defined by a greater change in dopant concentration per unit of depth compared to the first doping gradient.

2. The semiconductor diode structure of solution 1, wherein the first n-type region has a first average dopant concentration that is less than a second average dopant concentration that the second n-type region has.

3. The semiconductor diode structure of any of solutions 1-2, wherein the at least three n-type regions further comprise a third n-type region positioned between the first depth and the second depth, the third n-type region having a uniform doping.

4. The semiconductor diode structure of solution 3, wherein the uniform doping of the third n-type region corresponds to a background doping introduced into a n-type wafer material from which the semiconductor diode structure is formed.

5. A semiconductor opening switch (SOS) for producing a high power pulse, comprising: a plurality of semiconductor diode structures chained in series, each semiconductor diode structure comprising: one or more p-type regions positioned continuously to a first depth within the semiconductor diode structure; and two n-type regions positioned past a second depth within the semiconductor diode structure, the two n-type regions having different doping gradients.

6. The SOS of solution 5, wherein each of the different doping gradients of the two n-type regions is defined by a gradual change in dopant concentration over units of depth.

7. The SOS of any of solutions 5-6, wherein the plurality of semiconductor diode structures are identically manufactured with respect to the first depth and the second depth in each semiconductor diode structure.

8. The SOS of any of solutions 5-7, wherein an end of a first semiconductor diode structure is separated from an end of a following semiconductor diode structure by a layer of conductive epoxy.

9. The SOS of any of solutions 5-8, wherein each semiconductor diode structure further comprises a third n-type region positioned between the first depth and the second depth, the third n-type region having a uniform doping.

10. The SOS of any of solutions 5-9, wherein a greater one of the different doping gradients is nearer to an end of the semiconductor diode structure and a lesser one of the different doping gradients is nearer to the second depth within the semiconductor diode structure.

11. The SOS of any of solutions 5-10, wherein one of the two n-type regions located nearer to the bottom end has a higher average dopant concentration than the other one of the two n-type regions.

12. A method for manufacturing a SOS for pulse generation, the SOS comprising a series of diode structures, the method comprising: growing at least a portion of a diode structure from a crystal substrate, wherein the portion of the diode structure comprises: a first n-type region located at an end of the diode structure from which the diode structure is grown from the crystal substrate, the first n-type region having a first doping gradient, and a second n-type region positioned immediately deeper to the first n-type region and having a second doping gradient.

13. The method of solution 12, wherein the second doping gradient features a smaller change in dopant concentration per change in depth relative to the first doping gradient.

14. The method of any of solutions 12-13, wherein the first doping gradient and the second doping gradient are introduced into the first n-type region and the second n-type region respectively via diffusion or in situ doping during a crystal growth of the portion of the diode structure.

15. The method of any of solutions 12-14, further comprising: selecting a size of the first n-type region and the second n-type region to optimize pulse rise time for a fixed size of a p-type region.

16. The method of any of solutions 12-15, wherein the portion of the diode structure is grown within a layered wafer, and wherein the method further comprises: singulating the portion of the diode structure from the layered wafer.

17. The method of any of solutions 12-16, further comprising: growing a second portion of the diode structure, the second portion of the diode structure comprising a plurality of p-type regions, wherein a p-type dopant is introduced into the plurality of p-type regions during a crystal growth of the second portion of the diode structure.

18. A method comprising: selecting a first depth for a p-type portion of a diode structure based on a range of desired peak voltages for an output pulse to be produced by a switch device comprising a plurality of the diode structures; selecting a second depth for a n-type gradient portion of the diode structure to minimize a rise time of the output pulse given the first depth for the p-type portion; and manufacturing the diode structure according to the first depth and the second depth, wherein manufacturing the diode structure comprises growing the n-type gradient portion, from an end of the diode structure to the second depth, to include two different doping gradients.

19. The method of solution 18, wherein one of the two different doping gradients that is nearer to the end of the diode structure features a greater change in dopant concentration per change in depth than another one of the two different doping gradients that is nearer to the second depth.

20. The method of any of solutions 18-19, further comprising: assembling the diode structure in series with a plurality of other diode structures that are identically manufactured according to the first depth and the second depth to produce the switch device.

21. The method of any of solutions 18-20, wherein manufacturing the diode structure comprises singulating the diode structure and a plurality of other diode structures from a common wafer.

22. The method of any of solutions 18-21, wherein manufacturing the semiconductor diode structure further comprises: growing the p-type portion starting from the first depth, wherein a p-type dopant is introduced into the p-type portion during a crystal growth of the p-type portion.

23. The method of any of solutions 18-21, wherein manufacturing the semiconductor diode structure further comprises: growing the p-type portion starting from the first depth, wherein a p-type dopant is diffused into the p-type portion subsequent to a crystal growth of the p-type portion.

24. A technical solution for mitigating pre-pulses in pulses output by a semiconductor open switch comprising a series of semiconductor diode structures, as described in this patent document.

Although a few variations have been described in detail above, other modifications or additions are possible. In particular, further features and/or variations may be provided in addition to those set forth herein. Moreover, the example embodiments described above may be directed to various combinations and sub-combinations of the disclosed features and/or combinations and sub-combinations of several further features disclosed above. In addition, the logic flow depicted in the accompanying figures and/or described herein does not require the particular order shown, or sequential order, to achieve desirable results. Other embodiments may be within the scope of the following claims.

Only a few implementations and examples are described and other implementations, enhancements and variations can be made based on what is described and illustrated in this patent document. Moreover, the separation of various system components in the embodiments described in this patent document should not be understood as requiring such separation in all embodiments.

What is claimed is:

1. A semiconductor opening switch (SOS) for producing a high power pulse, comprising:
a plurality of semiconductor diode structures chained in series, each semiconductor diode structure comprising:
one or more p-type regions positioned contiguously to a first depth within the semiconductor diode structure; and
two n-type regions positioned past a second depth within the semiconductor diode structure, the two n-type regions having respective doping gradients having different changes in dopant concentration per unit depth.

2. The SOS of claim 1, wherein each of the different doping gradients of the two n-type regions is defined by a gradual change in dopant concentration over units of depth.

3. The SOS of claim 1, wherein the plurality of semiconductor diode structures are identically manufactured with respect to the first depth and the second depth in each semiconductor diode structure.

4. The SOS of claim 1, wherein an end of a first semiconductor diode structure is separated from an end of a following semiconductor diode structure by a layer of conductive epoxy.

5. The SOS of claim 1, wherein each semiconductor diode structure further comprises a third n-type region positioned between the first depth and the second depth, the third n-type region having a uniform doping.

6. The SOS of claim 1, wherein a greater one of the different doping gradients is nearer to an end of the semiconductor diode structure and a lesser one of the different doping gradients is nearer to the second depth within the semiconductor diode structure.

7. The SOS of claim 6, wherein one of the two n-type regions located nearer to the end has a higher average dopant concentration than the other one of the two n-type regions.

8. A semiconductor diode structure, comprising:
one or more p-type regions positioned contiguously in the semiconductor diode structure to a first depth within the semiconductor diode structure; and
at least three n-type regions positioned contiguously starting from the first depth of the semiconductor diode structure, the at least three n-type regions comprising:
a first n-type region followed by a second n-type region positioned past a second depth within the semiconductor diode structure, wherein the first n-type region has a first doping gradient and the second n-type region has a second doping gradient that is defined by a greater change in dopant concentration per unit of depth compared to the first doping gradient.

9. The semiconductor diode structure of claim 8, wherein the first n-type region has a first average dopant concentration that is less than a second average dopant concentration that the second n-type region has.

10. The semiconductor diode structure of claim 8, wherein the at least three n-type regions further comprise a third n-type region positioned between the first depth and the second depth, the third n-type region having a uniform doping.

11. The semiconductor diode structure of claim 10, wherein the uniform doping of the third n-type region corresponds to a background doping introduced into a n-type wafer material from which the semiconductor diode structure is formed.

12. A method comprising:
selecting a first depth for a p-type portion of a diode structure based on a range of desired peak voltages for an output pulse to be produced by a switch device comprising a plurality of the diode structures;
selecting a second depth for a n-type gradient portion of the diode structure to minimize a rise time of the output pulse given the first depth for the p-type portion; and
manufacturing the diode structure according to the first depth and the second depth, wherein manufacturing the diode structure comprises growing the n-type gradient portion, from an end of the diode structure to the second depth, to include two different doping gradients.

13. The method of claim 12, wherein one of the two different doping gradients that is nearer to the end of the diode structure features a greater change in dopant concentration per change in depth than another one of the two different doping gradients that is nearer to the second depth.

14. The method of claim 12, further comprising:
assembling the diode structure in series with a plurality of other diode structures that are identically manufactured according to the first depth and the second depth to produce the switch device.

15. The method of claim 14, wherein the plurality of other diode structures are identically manufactured from a common substrate with the diode structure, the first depth and the second depth being defined throughout the common substrate.

16. The method of claim 12, wherein manufacturing the diode structure comprises singulating the diode structure and a plurality of other diode structures from a common substrate.

17. The method of claim 12, wherein manufacturing the diode structure further comprises:
growing the p-type portion starting from the first depth, wherein a p-type dopant is introduced into the p-type portion during a crystal growth of the p-type portion.

18. The method of claim 12, wherein manufacturing the diode structure further comprises:
growing the p-type portion starting from the first depth, wherein a p-type dopant is diffused into the p-type portion subsequent to a crystal growth of the p-type portion.

19. The method of claim 12, wherein manufacturing the diode structure further comprises growing the n-type portion based on introducing a n-type dopant during a crystal growth of the n-type portion.

20. The method of claim 12, wherein selecting a second depth for the n-type gradient portion comprises selecting respective depth-wise sizes of the two different doping gradients included in the n-type gradient portion to minimize the rise time of the output pulse given the first depth for the p-type portion.
